(19) United States
(12) Patent Application Publication
(10) Pub. No.: US 2026/0190576 A1
(43) Pub. Date: Jul. 2, 2026

(54) DISPLAY DEVICE

(71) Applicant: LG Display Co., Ltd., Seoul (KR)

(72) Inventors: Kwang-Su LIM, Paju-si (KR); So-Young LEE, Paju-si (KR); Young-In JANG, Paju-si (KR)

(73) Assignee: LG Display Co., Ltd., Seoul (KR)

(21) Appl. No.: 19/321,373

(22) Filed: Sep. 8, 2025

(30) Foreign Application Priority Data
Nov. 18, 2024 (KR) 10-2024-0164118

(51) Int. Cl. H10H 29/49

(52) U.S. Cl. CPC H10H 29/49

(57) ABSTRACT

A display device and a method of manufacturing the same are discussed. The display device can include a substrate, a light-emitting element over the substrate and having a first element electrode and a second element electrode, a first electrode electrically connected to the first element electrode, and a second electrode electrically connected to the second element electrode. The light-emitting element includes a first mesa area and a second mesa area spaced apart from each other. The second element electrode is disposed in the first mesa area, and the second mesa area is disposed between the first element electrode and the first mesa area.

### CROSS-REFERENCE TO RELATED APPLICATION

The present application claims priority to Korean Patent Application No. 10-2024-0164118, filed in the Republic of Korea on Nov. 18, 2024, the entire contents of which are hereby expressly incorporated by reference into the present application.

### BACKGROUND

### Technical Field

The present disclosure relates to a display device, and more particularly, for example, without limitation, to a display device including a light-emitting element and a method of manufacturing the same.

### Discussion of the Related Art

As the information society progresses, a demand for different types of display devices increases, and flat panel display devices (FPD) such as liquid crystal display devices and light-emitting diode display devices have been developed and applied to various fields.

Among the flat panel display devices, light-emitting diode display devices emit light due to the radiative recombination of an exciton. The exciton is formed from an electron and a hole by injecting charges into a light-emitting layer between a cathode for injecting electrons and an anode for injecting holes in a light-emitting diode.

The light-emitting diode display device can offer various advantages and improved properties. For instance, compared to the liquid crystal display device, since it is self-luminous, the light-emitting diode display device has a wide viewing angle. Further, since a backlight unit is not required, the light-emitting diode display device has an ultra-thin thickness and light weight. In addition, the light-emitting diode display device is also advantageous in power consumption.

The light-emitting diode display device can include inorganic-based light-emitting elements and organic-based light-emitting elements. The inorganic-based light-emitting elements have relatively excellent stability, fast response characteristics, and high contrast ratios, and micro light-emitting diodes (micro LEDs or uLED) are widely used as the inorganic-based light-emitting elements for high resolution.

The inorganic-based light-emitting elements are formed on an element substrate and are transferred to an array substrate of a display device. Then, signal electrodes for transmitting signals are formed on the array substrate of the display device. However, since the size of the light-emitting element is relatively very small, a distance between the signal electrodes is very short, so that an electrical short-circuiting can occur between the electrodes of the light-emitting element.

The description provided in the discussion of the related art section should not be assumed to be prior art merely because it is mentioned in or associated with that section. The discussion of the related art section can include information that describes one or more aspects of the subject technology, and the description in this section does not limit the disclosure.

### SUMMARY OF THE DISCLOSURE

Accordingly, embodiments of the present disclosure are directed to a display device and a method of manufacturing the same, which substantially obviate one or more of the problems due to limitations and disadvantages of the related art.

An aspect of the present disclosure is to provide a display device capable of preventing or reducing an electrical short-circuiting between the electrodes of a light-emitting element in a display device.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a display device includes a substrate; a light-emitting element over the substrate and including a first element electrode and a second element electrode; a first electrode electrically connected to the first element electrode; and a second electrode electrically connected to the second element electrode, wherein the light-emitting element includes a first mesa area and a second mesa area spaced apart from each other, and wherein the second element electrode is disposed in the first mesa area, and the second mesa area is disposed between the first element electrode and the first mesa area. Further, according to aspects of the present disclosure, a method of manufacturing the display device discussed above is provided.

Other systems, methods, features and advantages will be, or will become, apparent to one with skill in the art upon examination of the following drawings and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is a view schematically showing a display device according to one or more embodiments of the present disclosure;

FIG. 2 is a schematic cross-sectional view of a display device according to one or more embodiments of the present disclosure;

FIG. 3 is a schematic plan view of a display panel of a display device according to an embodiment of the present disclosure;

FIG. 4 is a schematic cross-sectional view of a display panel of a display device according to another example of the embodiment of the present disclosure; and

FIGS. 5A to 5J are schematic cross-sectional views of a display panel in steps of manufacturing a display device according to an embodiment of the present disclosure.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted or can be briefly discussed. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

Any implementation described herein as an “example” is not necessarily to be construed as preferred or advantageous over other implementations.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure.

Further, in the following description of the present disclosure, when a detailed description of a known related art is determined to unnecessarily obscure the gist of the present disclosure, the detailed description thereof will be omitted herein or can be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components can be present between A and B, unless explicitly specified as “A is in direct contact with B.”

Although the terms first, second, and the like are used to describe various components, these components are not substantially limited by these terms. These terms are used only to distinguish one component from another component, and may not define any order or sequence. Therefore, a first component described below can substantially be a second component within the technical idea of the present disclosure.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art. Further, the term “can” fully encompasses all the meanings and coverages of the term “may” and vice versa.

Rather, these embodiments can be provided so that this disclosure can be sufficiently thorough and complete to assist those skilled in the art to fully understand the scope of the present disclosure. Furthermore, the present disclosure is only defined by scopes of claims.

Features of various embodiments of the present disclosure can be partially or entirely united or combined with each other, technically various interlocking and driving are possible, and each of the embodiments can be independently implemented with respect to each other or implemented together in a related relationship.

Hereinafter, example embodiments of the present disclosure will be described in detail with reference to accompanying drawings. All the components of each display device/apparatus according to all embodiments of the present disclosure are operatively coupled and configured.

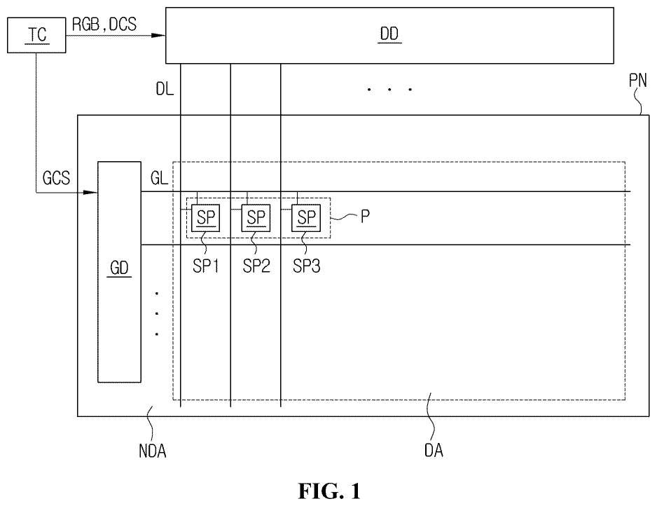

FIG. 1 is a view schematically showing a display device according to an embodiment of the present disclosure. The display device can be a micro LED (light-emitting diode) display device or a mini LED display device. However, embodiments of the present disclosure are not limited thereto, and in other embodiments, for example, the display device can be an organic light-emitting diode (OLED) display device.

Referring to FIG. 1, the display device according to an embodiment of the present disclosure can include a display panel PN, a timing controller TC, a data driver DD, and a gate driver GD.

The timing controller TC can generate image data RGB, a data control signal DCS, and a gate control signal GCS using an image signal and a plurality of timing signals, such as a data enable signal, a horizontal synchronization signal, a vertical synchronization signal, and a clock, transmitted from an external system such as a graphic card or a TV system.

In addition, the timing controller TC can transmit the generated image data RGB and the generated data control signal DCS to the data driver DD and can transmit the generated gate control signal GCS to the gate driver GD.

The data driver DD can generate a data voltage, which is a data signal, using the image data RGB and the data control signal DCS transmitted from the timing controller TC and can apply the generated data voltage to a data line DL of the display panel PN.

The gate driver GD can generate a gate voltage, which is a gate signal, using the gate control signal GCS transmitted from the timing controller TC and can apply the generated gate voltage to a gate line GL of the display panel PN.

Here, the gate driver GD can be provided as a gate-in-panel (GIP) type formed together on a substrate of the display panel PN on which the gate line GL, the data line DL, and sub-pixels SP are formed and can be disposed in a non-display area NDA.

In the embodiment of FIG. 1, the gate driver GD can be disposed on one side of the display panel PN, but in other embodiments, two gate drivers can be disposed on both sides of the display panel PN, respectively.

The display panel PN can include a display area DA for displaying an image and a non-display area NDA surrounding the display area DA entirely or in part(s). The display panel PN can display the image using the gate voltage supplied from the gate driver GD and the data voltage supplied from the data driver DD. To do this, the display panel PN can include a plurality of pixels P, a plurality of gate lines GL, and a plurality of data lines DL disposed in the display area DA.

Each of the plurality of pixels P can include a plurality of sub-pixels SP, and gate lines GL and the data lines DL can cross each other to define each pixel P and/or the sub-pixels SP. For example, each of the plurality of pixels P can include first, second, and third sub-pixels SP1, SP2, and SP3, and the first, second, and third sub-pixels SP1, SP2, and SP3 can be red, green, and blue sub-pixels, respectively.

At least one light-emitting diode, a plurality of thin film transistors, and at least one storage capacitor can be provided in each sub-pixel SP.

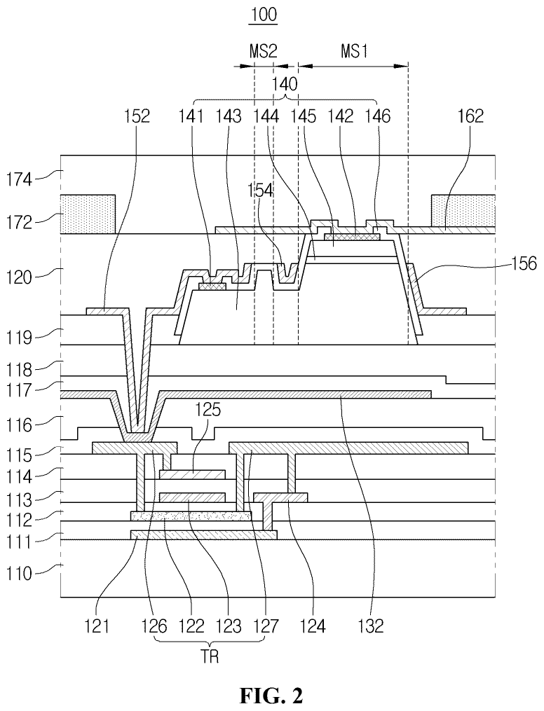

A cross sectional structure of the display device according to the embodiment of the present disclosure will be described in detail with reference to FIG. 2. Each pixel/subpixel of FIG. 1 can have the configuration shown in FIG. 2.

FIG. 2 is a schematic cross-sectional view of a display device according to the embodiment of the present disclosure and shows a cross-section corresponding to one sub-pixel.

Referring to FIG. 2, the display panel 100 of the display device according to the embodiment of the present disclosure can include a thin film transistor TR and a light-emitting element 140 over a substrate 110. A first element electrode 141 of the light-emitting element 140 can be connected to the thin film transistor TR, and a second element electrode 142 of the light-emitting element 140 can be connected to a power line.

Specifically, a light-shielding layer 121 can be provided on the substrate 110. The substrate 110 can be a glass substrate or a plastic substrate. For example, polyimide can be used for the plastic substrate, and the plastic substrate can have a stacked structure including at least one polyimide layer and at least one inorganic layer. However, embodiments of the present disclosure are not limited thereto.

The light-shielding layer 121 can be formed of a conductive material such as metal. For example, the light-shielding layer 121 can be formed of one or more of: aluminum (Al), copper (Cu), molybdenum (Mo), titanium (Ti), chromium (Cr), nickel (Ni), tungsten (W), and an alloy thereof. The light-shielding layer 121 can have a single-layered structure or a multiple-layered structure.

A buffer layer 111 can be provided on the light-shielding layer 121. The buffer layer 111 can be disposed substantially all over the substrate 110. The buffer layer 111 can be formed as a single layer or multiple layers of an inorganic insulating material. The inorganic insulating material of the buffer layer 111 can include silicon nitride (SiNx), silicon oxide (SiOx), or silicon oxynitride (SiON).

An active layer 122 can be provided on the buffer layer 111. The active layer 122 can overlap the light-shielding layer 121, and the light-shielding layer 121 can block light incident on the active layer 122 and prevent the active layer 122 from deteriorating due to the light.

The active layer 122 can include a channel region at its central part and source and drain regions at both sides of the channel region. The active layer 122 can be formed of an oxide semiconductor material. Alternatively, the active layer 122 can be formed of polycrystalline silicon, and in this case, both ends of the active layer 122 can be doped with impurities.

A gate insulation layer 112 can be provided on the active layer 122 and the buffer layer 111. The gate insulation layer 112 can be disposed substantially all over the substrate 110. The gate insulation layer 112 can be formed as a single layer or multiple layers of an inorganic insulating material. The inorganic insulating material of the gate insulation layer 112 can include silicon nitride (SiNx), silicon oxide (SiOx), or silicon oxynitride (SiON).

A gate electrode 123 and an auxiliary electrode 124 can be formed on the gate insulation layer 112. The gate electrode 123 can overlap the active layer 122 and can be disposed to correspond to the central part of the active layer 122. Accordingly, the gate electrode 123 can also overlap the light-shielding layer 121.

The auxiliary electrode 124 can be spaced apart from the active layer 122 and can overlap the light-shielding layer 121. The auxiliary electrode 124 can be in contact with the light-shielding layer 121 through a contact hole provided in the buffer layer 111 and the gate insulation layer 112.

The gate electrode 123 and the auxiliary electrode 124 can be formed of a conductive material such as metal. For example, the gate electrode 123 and the auxiliary electrode 124 can be formed of one or more of: aluminum (Al), copper (Cu), molybdenum (Mo), titanium (Ti), chromium (Cr), nickel (Ni), tungsten (W), and an alloy thereof. The gate electrode 123 and the auxiliary electrode 124 can have a single-layered structure or a multiple-layered structure.

A first interlayer insulation layer 113 can be provided on the gate electrode 123 and the auxiliary electrode 124. The first interlayer insulation layer 113 can be disposed substantially all over the substrate 110. The first interlayer insulation layer 113 can be formed as a single layer or multiple layers of an inorganic insulating material. The inorganic insulating material of the first interlayer insulation layer 113 can include silicon nitride (SiNx), silicon oxide (SiOx), or silicon oxynitride (SiON).

A capacitor electrode 125 can be provided on the first interlayer insulation layer 113. The capacitor electrode 125 can overlap the gate electrode 123 to thereby form a storage capacitor with the first interlayer insulation layer 113 therebetween as a dielectric. The capacitor electrode 125 can also overlap the light-shielding layer 121.

The capacitor electrode 125 can be formed of a conductive material such as metal. For example, the capacitor electrode 125 can be formed of one or more of: aluminum (Al), copper (Cu), molybdenum (Mo), titanium (Ti), chromium (Cr), nickel (Ni), tungsten (W), and an alloy thereof. The capacitor electrode 125 can have a single-layered structure or a multiple-layered structure.

A second interlayer insulation layer 114 can be provided on the capacitor electrode 125. The second interlayer insulation layer 114 can be disposed substantially all over the substrate 110. The second interlayer insulation layer 114 can be formed as a single layer or multiple layers of an inorganic insulating material. The inorganic insulating material of the second interlayer insulation layer 114 can include silicon nitride (SiNx), silicon oxide (SiOx), or silicon oxynitride (SiON).

A source electrode 126 and a drain electrode 127 can be provided on the second interlayer insulation layer 114. The source electrode 126 and the drain electrode 127 can be spaced apart from each other with the gate electrode 123 positioned therebetween and can be in contact with both ends of the active layer 122 through contact holes provided in the gate insulation layer 112 and the first and second interlayer insulation layers 113 and 114.

In addition, the source electrode 126 can overlap the capacitor electrode 125 and can be in contact with the capacitor electrode 125 through a contact hole provided in the second interlayer insulation layer 114. The drain electrode 127 can overlap the auxiliary electrode 124 and can be in contact with the auxiliary electrode 124 through a contact hole provided in the first and second interlayer insulation layers 113 and 114.

The active layer 122, the gate electrode 123, the source electrode 126, and the drain electrode 127 can constitute a thin film transistor TR. The thin film transistor TR can be a driving transistor.

The source electrode 126 and the drain electrode 127 can be formed of a conductive material such as metal. For example, the source electrode 126 and the drain electrode 127 can be formed of one or more of: aluminum (Al), copper (Cu), molybdenum (Mo), titanium (Ti), chromium (Cr), nickel (Ni), tungsten (W), and an alloy thereof. The source electrode 126 and the drain electrode 127 can have a single-layered structure or a multiple-layered structure.

A first passivation layer 115 and an overcoat layer 116 can be provided on the source electrode 126 and the drain electrode 127. The first passivation layer 115 and the overcoat layer 116 can be disposed substantially all over the substrate 110.

The first passivation layer 115 can be formed as a single layer or multiple layers of an inorganic insulating material. The inorganic insulating material of the first passivation layer 115 can include silicon nitride (SiNx), silicon oxide (SiOx), or silicon oxynitride (SiON). The first passivation layer 115 can be omitted.

The overcoat layer 116 can eliminate a step difference due to the layers thereunder and can have a substantially flat top surface. For example, the overcoat layer 116 can be formed of an organic insulating material such as photosensitive acrylic polymer (photo acryl).

A reflection electrode 132 can be provided on the overcoat layer 116. The reflection electrode 132 can overlap the thin film transistor TR. The reflection electrode 132 can be in contact with the source electrode 126 through a contact hole provided in the first passivation layer 115 and the overcoat layer 116. Accordingly, the reflection electrode 132 can be electrically connected to the capacitor electrode 125 through the source electrode 126.

The reflection electrode 132 can be formed of a metal having relatively high reflectance. For example, the reflection electrode 132 can be formed of aluminum (Al), silver (Ag), or chromium (Cr).

A second passivation layer 117 can be provided on the reflection electrode 132. The second passivation layer 117 can be disposed substantially all over the substrate 110.

The second passivation layer 117 can be formed as a single layer or multiple layers of an inorganic insulating material. The inorganic insulating material of the second passivation layer 117 can include silicon nitride (SiNx), silicon oxide (SiOx), or silicon oxynitride (SiON). The second passivation layer 117 can be omitted.

An adhesive layer 118 can be provided on the second passivation layer 117. The adhesive layer 118 can be disposed substantially all over the substrate 110 and can fix the light-emitting element 140 to be transferred thereon.

The adhesive layer 118 can have a substantially flat top surface. For example, the adhesive layer 118 can be formed of an organic insulating material such as photosensitive acrylic polymer (photo acryl). Alternatively, the adhesive layer 118 can be formed of one of a polyimide (PI) resin, an epoxy resin, a urethane resin, and a polydimethylsiloxane (PDMS) resin.

The light-emitting element 140 can be provided on the adhesive layer 118. The light-emitting element 140 can overlap the reflection electrode 132. In addition, the light-emitting element 140 can also overlap the thin film transistor TR and the light-shielding layer 121.

The light-emitting element 140 can be provided in the form of a micro light-emitting diode chip (micro LED chip or uLED chip) including an n-electrode, an n-type layer, an active layer, a p-type layer, and a p-electrode. The light-emitting element 140 can have a lateral structure in which the n-electrode and the p-electrode are provided on the same side (for example, a first side opposite to a second side facing the substrate 110) and light is emitted through the first side provided with the n-electrode and the p-electrode (for example, the first side opposite to the second side facing the substrate 110).

However, embodiments of the present disclosure are not limited thereto. In other embodiments, the light-emitting element 140 can have a flip-chip structure in which the n-electrode and the p-electrode are provided on the same side (for example, the second side facing the substrate 110) and light is emitted through the first side opposite to the second side provided with the n-electrode and the p-electrode. Alternatively, the light-emitting element 140 can have a vertical structure in which the n-electrode and the p-electrode are provided on opposite sides (for example, the second side facing the substrate 110 and the first side opposite to the second side), respectively.

The light-emitting element 140 can include the first element electrode 141, the second element electrode 142, a light-emitting structure 143, 144, and 145, and a protection layer 146.

The first element electrode 141 and the second element electrode 142 can be provided on the light-emitting structure 143, 144, and 145 and can be spaced apart from each other. The first element electrode 141 and the second element electrode 142 can be disposed at different heights. For example, the second element electrode 142 can be disposed higher than the first element electrode 141.

Here, the first element electrode 141 can be an n-electrode, and the second element electrode 142 can be a p-electrode. The first element electrode 141 can be a cathode, and the second element electrode 142 can be an anode.

However, embodiments of the present disclosure are not limited thereto. Alternatively, in other embodiments, the first element electrode 141 can be a p-electrode, and the second element electrode 142 can be an n-electrode. In this case, the first element electrode 141 can be an anode, and the second element electrode 142 can be a cathode.

The first element electrode 141 and the second element electrode 142 can be formed of a conductive material. For example, the first element electrode 141 and the second element electrode 142 can be formed of a transparent conductive material such as indium tin oxide (ITO) or indium zinc oxide (IZO) or an opaque conductive material such as titanium (Ti), gold (Au), silver (Ag), copper (Cu), or an alloy thereof. However, embodiments of the present disclosure are not limited thereto.

The light-emitting structure 143, 144, and 145 can include a first semiconductor layer 143, a light-emitting layer 144, and a second semiconductor layer 145. The light-emitting layer 144 can be disposed between the first semiconductor layer 143 and the second semiconductor layer 145.

Meanwhile, the light-emitting structure 143, 144, and 145 can have a first mesa area MS1 and a second mesa area MS2. The first mesa area MS1 can include the first semiconductor layer 143, the light-emitting layer 144, and the second semiconductor layer 145. The second mesa area MS2 can include the first semiconductor layer 143. Accordingly, a height of the second mesa area MS2 can be lower than a height of the first mesa area MS1, and the second mesa area MS2 can be positioned lower than the light-emitting layer 144 and the second semiconductor layer 145. In addition, a width of the second mesa area MS2 can be smaller than a width of the first mesa area MS1.

The second element electrode 142 can be disposed in the first mesa area MS1, the first element electrode 141 can be spaced apart from the first mesa area MS1 and the second mesa area MS2, and the second mesa area MS2 can be disposed between the first element electrode 141 and the first mesa area MS1.

The first semiconductor layer 143 and the second semiconductor layer 145 can be formed by doping n-type or p-type impurities into a semiconductor material. For example, the first semiconductor layer 143 and the second semiconductor layer 145 can be formed by doping n-type or p-type impurities into gallium nitride (GaN), indium aluminum phosphide (InAlP), or gallium arsenide (GaAs). In addition, for example, the n-type impurities can be silicon (Si), germanium (Ge), or indium (Sn), and the p-type impurities can be magnesium (Mg), zinc (Zn), or beryllium (Be). However, embodiments of the present disclosure are not limited thereto.

The first semiconductor layer 143 can have a larger area than the second semiconductor layer 145. At least a part of the first semiconductor layer 143 can protrude outside the second semiconductor layer 145. In this case, the first element electrode 141 and the second mesa area MS2 can be provided on the first semiconductor layer 143 protruding outside the second semiconductor layer 145.

The light-emitting layer 144 can receive electrons and holes from the first semiconductor layer 143 and the second semiconductor layer 145, respectively, and emit light. The light-emitting layer 144 can be formed of a single quantum well (SQW) structure or a multi quantum well (MQW) structure. For example, the light-emitting layer 144 can be formed of indium gallium nitride (InGaN) or gallium nitride (GaN), but is not limited thereto.

The protection layer 146 can be provided on the light-emitting structure 143, 144, and 145 provided with the first element electrode 141 and the second element electrode 142 thereon. The protection layer 146 can cover and protect the first element electrode 141, the second element electrode 142, and the light-emitting structure 143, 144, and 145 and can partially expose top surfaces of the first element electrode 141 and the second element electrode 142.

The protection layer 146 can be formed as a single layer or multiple layers of an inorganic insulating material. The inorganic insulating material of the protection layer 146 can include silicon nitride (SiNx), silicon oxide (SiOx), or silicon oxynitride (SiON).

A first planarization layer 119 can be provided on the adhesive layer 118 provided with the light-emitting element 140 thereon. The first planarization layer 119 can be disposed substantially all over the substrate 110.

The first planarization layer 119 can partially surround a side surface of the light-emitting element 140 and can fix and protect the light-emitting element 140. A thickness of the first planarization layer 119 can be smaller than a thickness of the light-emitting element 140 and smaller than a thickness of the first semiconductor layer 143. The first planarization layer 119 can be disposed lower than the first element electrode 141 and the second element electrode 142 of the light-emitting element 140 to thereby expose the first element electrode 141 and the second element electrode 142.

The first planarization layer 119 can be formed of an organic insulating material such as photosensitive acrylic polymer (photo acryl). The first planarization layer 119 can have a substantially flat top surface.

A first electrode 152 can be provided on the first planarization layer 119. The first electrode 152 can partially overlap the light-emitting element 140 and can be in contact with the first element electrode 141 of the light-emitting element 140. The first electrode 152 can be spaced apart from the first mesa area MS1 and the second mesa area MS2.

In addition, the first electrode 152 can overlap the reflection electrode 132 and can be in contact with the reflection electrode 132 through a contact hole provided in the second passivation layer 117, the adhesive layer 118, and the first planarization layer 119.

Accordingly, the first electrode 152 can be electrically connected to the source electrode 126 of the thin film transistor TR through the reflection electrode 132. The first element electrode 141 of the light-emitting element 140 can be electrically connected to the source electrode 126 of the thin film transistor TR through the first electrode 152 and the reflection electrode 132.

Meanwhile, a first dummy pattern 154 and a second dummy pattern 156 can be further provided on the first planarization layer 119 and the light-emitting element 140 and can be formed of the same material as the first electrode 152. The first dummy pattern 154 can be disposed between the first mesa area MS1 and the second mesa area MS2. The first dummy pattern 154 can be spaced apart from the first electrode 152 and the second dummy pattern 156 and can be disposed between the first electrode 152 and the second dummy pattern 156. Accordingly, the second mesa area MS2 can be disposed between the first electrode 152 and the first dummy pattern 154.

In addition, the second dummy pattern 156 can be disposed outside the light-emitting element 140 corresponding to the first mesa area MS1 and can be in contact with the protection layer 146 and the first planarization layer 119. The second dummy pattern 156 can be omitted.

The first electrode 152, the first dummy pattern 154, and the second dummy pattern 156 can be formed of a transparent conductive material such as indium tin oxide (ITO) or indium zinc oxide (IZO). Alternatively, the first electrode 152, the first dummy pattern 154, and the second dummy pattern 156 can be formed of a metal such as aluminum (Al), copper (Cu), molybdenum (Mo), titanium (Ti), chromium (Cr), nickel (Ni), tungsten (W), or an alloy thereof.

A second planarization layer 120 can be provided on the first electrode 152, the first dummy pattern 154, and the second dummy pattern 156. The second planarization layer 120 can be disposed substantially all over the substrate 110.

The second planarization layer 120 can partially surround the side surface of the light-emitting element 140 and can flatten the top surface of the substrate 110 provided with the light-emitting element 140 together with the first planarization layer 119. The second planarization layer 120 can fix and protect the light-emitting element 140 together with the adhesive layer 118 and the first planarization layer 119.

The second planarization layer 120 can cover the light-emitting element 140, the first electrode 152, the first dummy pattern 154, and the second dummy pattern 156 and can expose a part of the light-emitting element 140. Specifically, the second planarization layer 120 can cover the first element electrode 141, the first electrode 152, the first dummy pattern 154, and the second dummy pattern 156 and can partially expose the second element electrode 142 of the light-emitting element 140.

The second planarization layer 120 can be formed of an organic insulating material such as photosensitive acrylic polymer (photo acryl).

Next, a second electrode 162 can be provided on the second planarization layer 120. The second electrode 162 can overlap the light-emitting element 140.

Specifically, the second electrode 162 can overlap the first element electrode 141 and the second element electrode 142 of the light-emitting element 140 and can be in contact with the exposed second element electrode 142. In addition, the second electrode 162 can also overlap the first electrode 152, the first dummy pattern 154, and the second dummy pattern 156.

The second electrode 162 can be formed of a transparent conductive material such as indium tin oxide (ITO) or indium zinc oxide (IZO). Alternatively, the second electrode 162 can be formed of a metal such as aluminum (Al), copper (Cu), molybdenum (Mo), titanium (Ti), chromium (Cr), nickel (Ni), tungsten (W), or an alloy thereof.

A bank layer 172 can be provided on the second planarization layer 120 provided with the second electrode 162 thereon. The bank layer 172 can be a black bank blocking light. The bank layer 172 may not overlap the light-emitting element 140 and can be spaced apart from the light-emitting element 140. The bank layer 172 can prevent or reduce light from the light-emitting element 140 provided in a sub-pixel from being output through a sub-pixel adjacent thereto. Here, the bank layer 172 can partially overlap and contact the second electrode 162.

The bank layer 172 can include a back component absorbing light. For example, the black component can include a black pigment and/or carbon black. However, embodiments of the present disclosure are not limited thereto.

A third planarization layer 174 can be provided on the bank layer 172. The third planarization layer 174 can be disposed substantially all over the substrate 110. The third planarization layer 174 can cover and be in contact with the second electrode 162, the bank layer 172, and the second planarization layer 120.

The third planarization layer 174 can be formed of an organic insulating material such as photosensitive acrylic polymer (photo acryl) and can have a substantially flat top surface.

As such, in the display device according to the embodiment of the present disclosure, by providing the second mesa area MS2 between the first element electrode 141 and the first mesa area MS1 and forming the first dummy pattern 154 separated from the first electrode 152 by the second mesa area MS2, it is possible to prevent or reduce an electrical short-circuiting problem between the first and second element electrodes 141 and 142 of the light-emitting element 140 due to the contact between the first electrode 152 and the second electrode 162. This will be described in detail later.

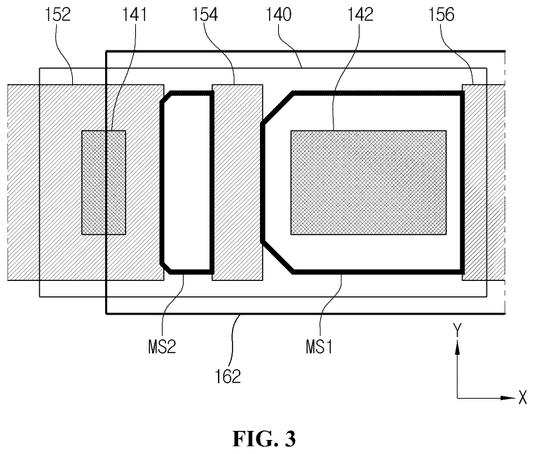

A planar configuration of a light-emitting element of a display device according to an embodiment of the present disclosure will be described with reference to FIG. 3.

FIG. 3 is a schematic plan view of a display panel of a display device according to an embodiment of the present disclosure and shows a light-emitting element and first and second electrodes.

Referring to FIG. 3, in the display device according to the embodiment of the present disclosure, the light-emitting element 140 can have the first mesa area MS1 and the second mesa area MS2 spaced apart from each other in a first direction X. The second element electrode 142 of the light-emitting element 140 can be disposed in the first mesa area MS1. The first element electrode 141 can be spaced apart from the first mesa area MS1 and the second mesa area MS2 in the first direction X. The second mesa area MS2 can be disposed between the first element electrode 141 and the first mesa area MS1 in the first direction X.

The first electrode 152, the first dummy pattern 154, and the second dummy pattern 156 can be provided to overlap the light-emitting element 140. The first dummy pattern 154 can be disposed between the first electrode 152 and the second dummy pattern 156 in the first direction X.

The first electrode 152 can overlap and be in contact with the first element electrode 141 and can be spaced apart from the second element electrode 142. The first electrode 152 can be spaced apart and electrically separated from the first dummy pattern 154 and the second dummy pattern 156.

The second mesa area MS2 can be disposed between the first electrode 152 and the first dummy pattern 154 in the first direction X, and the first mesa area MS1 and the second mesa area MS2 can be disposed between the first electrode 152 and the second dummy pattern 156 in the first direction X.

In addition, the first dummy pattern 154 can be disposed between the first mesa area MS1 and the second mesa area MS2 in the first direction X. The first dummy pattern 154 can be spaced apart and electrically separated from the first element electrode 141 and the second element electrode 142.

Meanwhile, the second electrode 162 can be provided to overlap the light-emitting element 140. The second electrode 162 can overlap the first mesa area MS1 and the second element electrode 142 and can be in contact with the second element electrode 142. The second electrode 162 can overlap the first dummy pattern 154 and the second dummy pattern 156 and can also overlap the second mesa area MS2.

In addition, the second electrode 162 can also the first electrode 152 and the first element electrode 141. However, embodiments of the present disclosure are not limited thereto. Alternatively, the second electrode 162 can be spaced apart from the first electrode 152 and the first element electrode 141.

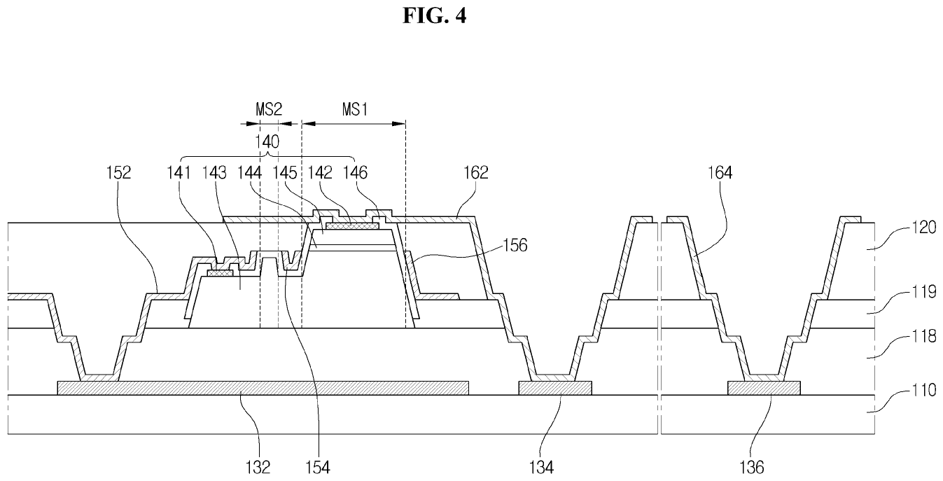

FIG. 4 is a schematic cross-sectional view of a display panel of a display device according to another example of the embodiment of the present disclosure and mainly shows a connection configuration between the light-emitting element and the electrodes. The display panel of FIG. 4 has substantially the same or similar configuration as that of the display panel of FIG. 2, except for the thin film transistor and the insulation layers. The same parts as those of the display panel of FIG. 2 are designated by the same or similar reference signs, and explanation for the same parts can be shortened or omitted.

Referring to FIG. 4, the reflection electrode 132, a power line 134, and a pad electrode 136 can be provided over the substrate 110.

Meanwhile, the thin film transistor TR, the plurality of insulation layers, and the plurality of electrode of FIG. 2 can be further provided between the substrate 110 and the reflection electrode 132.

The power line 134 can transmit a high potential voltage VDD. The pad electrode 136 can be provided in the non-display area NDA of FIG. 1 and can be an electrode for supplying a signal from the outside to a signal line in the display area DA.

The reflection electrode 132, the power line 134, and the pad electrode 136 can be formed of the same material and on the same layer.

The adhesive layer 118 can be provided on the reflection electrode 132, the power line 134, and the pad electrode 136 and can be disposed substantially all over the substrate 110. Meanwhile, the second passivation layer 117 of FIG. 2 can be further provided between the adhesive layer 118 and the reflection electrode 132.

The light-emitting element 140 having the first and second mesa areas MS1 and MS2 and the first planarization layer 119 can be provided on the adhesive layer 118. The first planarization layer 119 can partially surround the side surface of the light-emitting element 140 and can fix and protect the light-emitting element 140.

The first electrode 152, the first dummy pattern 154, and the second dummy pattern 156 can be provided on the light-emitting element 140 and the first planarization layer 119.

The first electrode 152 can overlap and be in contact with the first element electrode 141 of the light-emitting element 140 and can be in contact with the reflection electrode 132 through a contact hole provided in the adhesive layer 118 and the first planarization layer 119.

The first dummy pattern 154 can be disposed between the first mesa area MS1 and the second mesa area MS2. The first dummy pattern 154 can be separated from the second dummy pattern 156 by the first mesa area MS1 and can be separated from the first electrode 152 by the second mesa area MS2.

The second planarization layer 120 can be provided on the first electrode 152, the first dummy pattern 154, and the second dummy pattern 156 and can be disposed substantially all over the substrate 110. The second planarization layer 120 can partially surround the side surface of the light-emitting element 140 and can partially expose the second element electrode 142 of the light-emitting element 140.

In addition, the second planarization layer 120 can have contact holes respectively exposing the power line 134 and the pad electrode 136 together with the adhesive layer 118 and the first planarization layer 119 thereunder.

The second electrode 162 can be provided on the second planarization layer 120. The second electrode 162 can overlap the light-emitting element 140 and can be in contact with the second element electrode 142. In addition, the second electrode 162 can extend to overlap the power line 134 and can be in contact with the power line 134 through a contact hole provided in the adhesive layer 118, the first planarization layer 119, and the second planarization layer 120.

Meanwhile, an auxiliary pad 164 can be further provided on the second planarization layer 120. The auxiliary pad 164 can overlap the pad electrode 136 and can be in contact with the pad electrode 136 through a contact hole provided in the adhesive layer 118, the first planarization layer 119, and the second planarization layer 120.

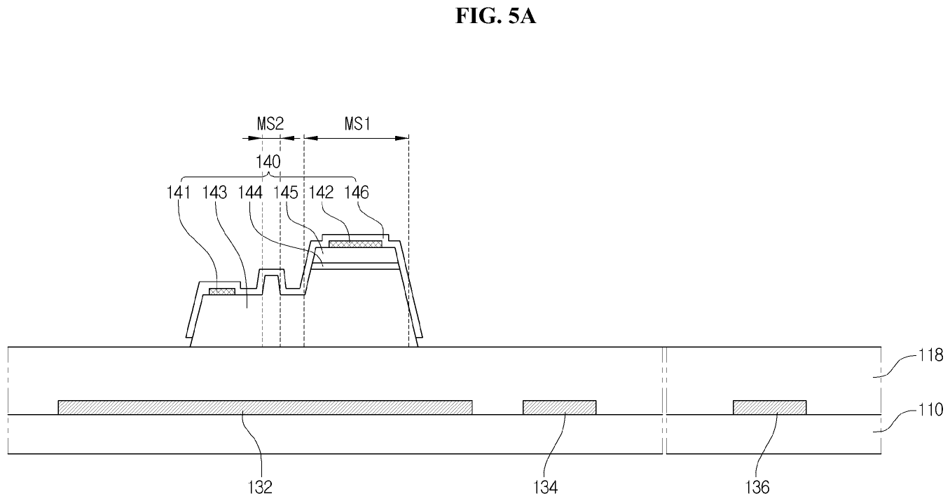

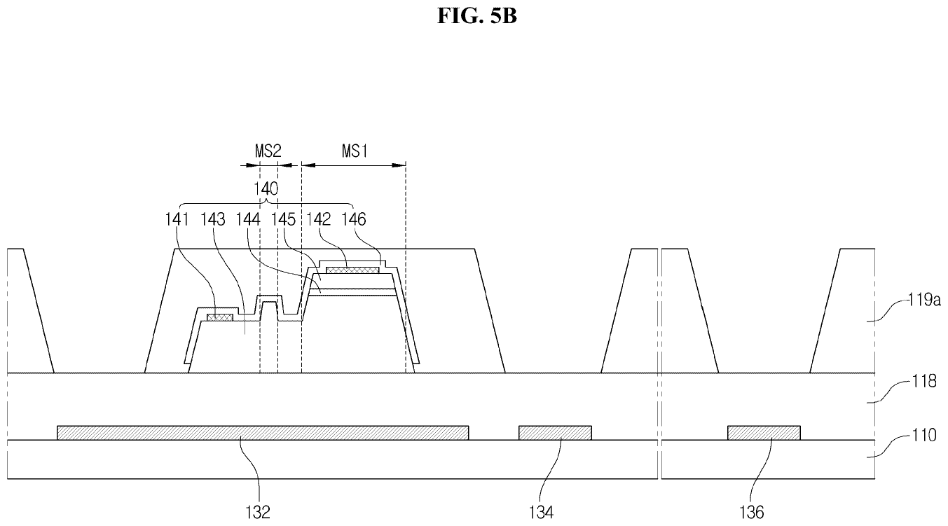

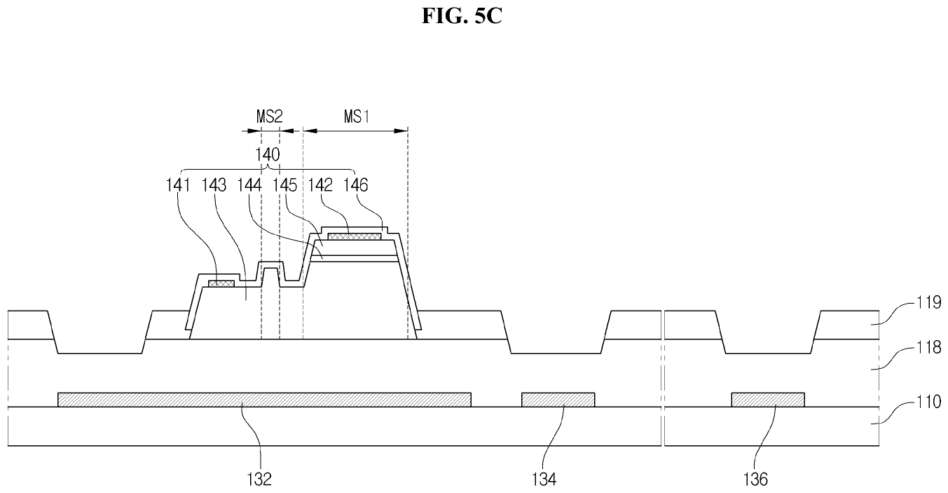

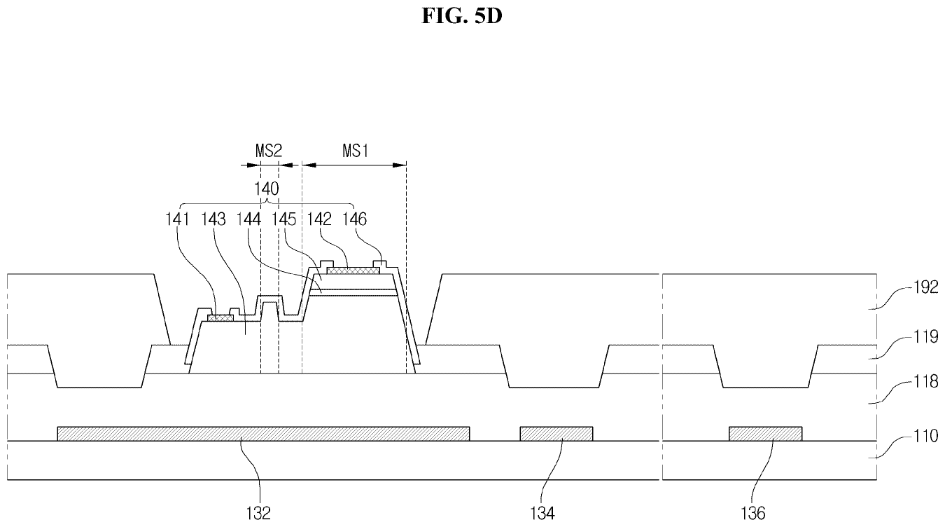

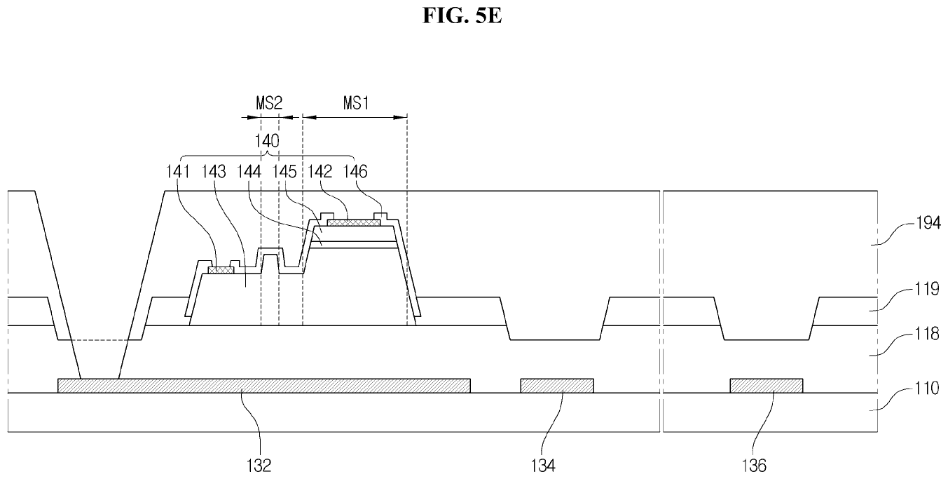

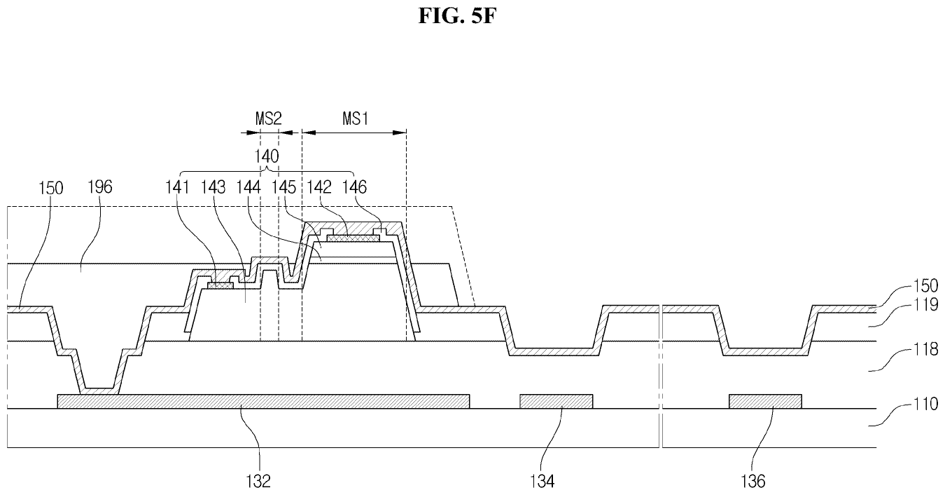

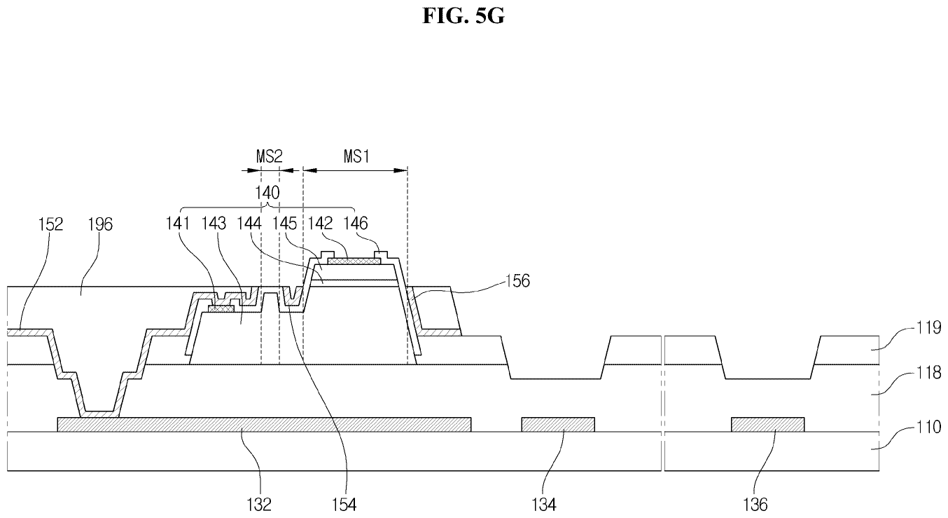

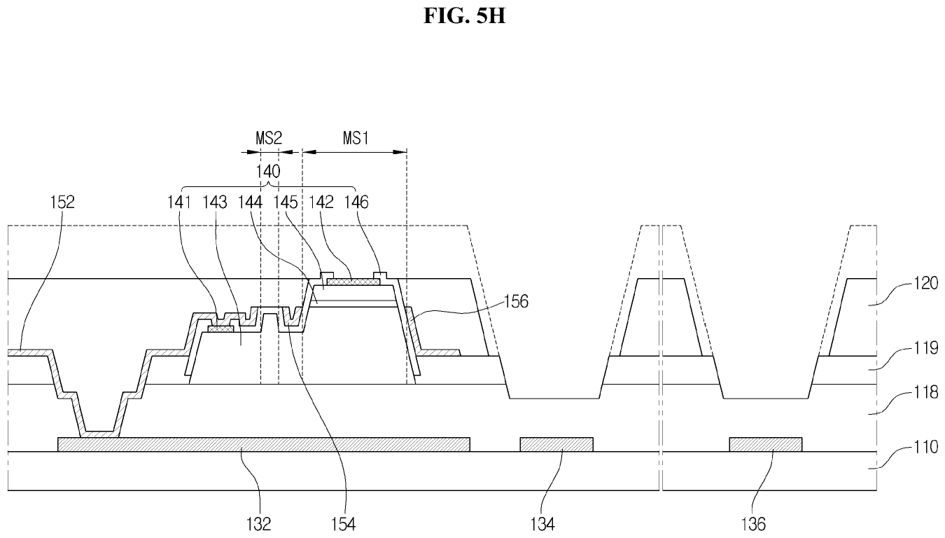

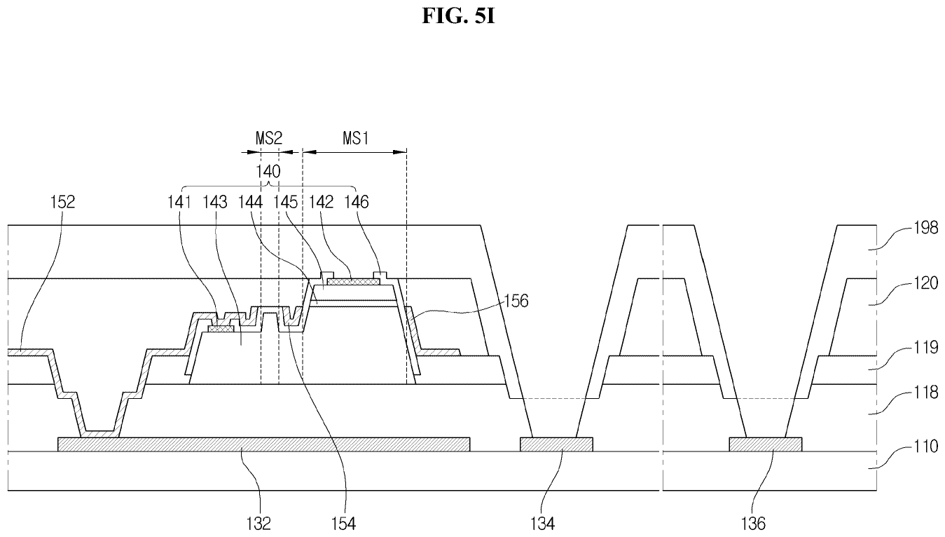

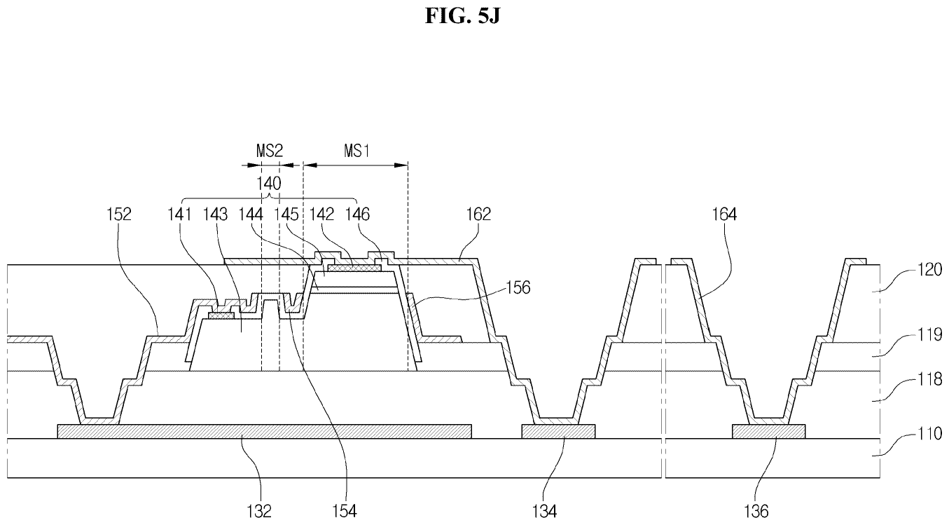

A method of manufacturing a display device according to an embodiment of the present disclosure will be described with reference to FIGS. 5A to 5J.

FIGS. 5A to 5J are schematic cross-sectional views of a display panel in steps of manufacturing a display device according to an embodiment of the present disclosure and show the display panel of FIG. 4 in steps of manufacturing the same.

Referring to FIG. 5A, the reflection electrode 132, the power line 134, and the pad electrode 136 can be formed over the substrate 110 by depositing a conductive material and patterning it through a photolithography process.

Then, the adhesive layer 118 can be formed on the reflection electrode 132, the power line 134, and the pad electrode 136 by applying an adhesive material, and the light-emitting element 140 can be transferred on the adhesive layer 118 corresponding to the reflection electrode 132. The light-emitting element 140 can overlap the reflection electrode 132.

As described above, the light-emitting element 140 can include the first element electrode 141, the second element electrode 142, the light-emitting structure 143, 144, and 145, and the protection layer 146 and can have the first and second mesa areas MS1 and MS2.

Here, the protection layer 146 of the light-emitting element 140 may not expose and can cover the first and second element electrodes 141 and 142.

Next, referring to FIG. 5B, an organic material layer 119a can be formed on the light-emitting element 140 and the adhesive layer 118 by applying an organic insulating material substantially all over the substrate 110, and can be patterned through a photolithography process, thereby partially exposing a top surface of the adhesive layer 118 corresponding to the reflection electrode 132, the power line 134, and the pad electrode 136.

In this case, the organic material layer 119a can have a thicker thickness than the light-emitting element 140. Accordingly, the organic material layer 119a can completely cover the light-emitting element 140.

Then, referring to FIG. 5C, the organic material layer 119a can be partially removed from its top surface through an ashing process, thereby forming the first planarization layer 119 having a smaller thickness than the organic material layer 119a. In this case, the adhesive layer 118 can also be partially removed through the ashing process.

The thickness of the first planarization layer 119 can be smaller than the thickness of the light-emitting element 140 to thereby expose the protection layer 146 on the first element electrode 141, the second element electrode 142, and the second mesa area MS2.

Next, referring to FIG. 5D, a first photoresist pattern 192 can be formed on the first planarization layer 119 through a photolithography process where photoresist is applied, exposed to light, and developed. The first photoresist pattern 192 can expose the light-emitting element 140.

Then, the protection layer 146 of the light-emitting element 140 can be selectively removed, thereby partially exposing the first and second element electrodes 141 and 142. In this case, the protection layer 146 can be removed through a dry etching process.

Next, referring to FIG. 5E, the first photoresist pattern 192 can be stripped and removed, and a second photoresist pattern 194 can be formed on the first planarization layer 119 and the light-emitting element 140 through a photolithography process where photoresist is applied, exposed to light, and developed. The second photoresist pattern 194 can partially expose the top surface of the adhesive layer 118 corresponding to the reflection electrode 132.

Then, the exposed adhesive layer 118 can be selectively removed using the second photoresist pattern 194 as an etching mask, thereby partially exposing a top surface of the reflection electrode 132.

Next, referring to FIG. 5F, the second photoresist pattern 194 can be stripped and removed, and a conductive material layer 150 can be formed on the first planarization layer 119 and the light-emitting element 140 by depositing a conductive material substantially all over the substrate 110. The conductive material layer 150 can cover the light-emitting element 140 and can be in contact with the first and second element electrodes 141 and 142 and the reflection electrode 132.

Then, a third photoresist pattern 196 covering the light-emitting element 140 can be formed on the conductive material layer 150 through a photolithography process where photoresist is applied, exposed to light, and developed. The third photoresist pattern 196 can be partially removed through an ashing process, thereby exposing the conductive material layer 150 on the first and second mesa areas MS1 and MS2.

Meanwhile, the third photoresist pattern 196 can cover the conductive material layer 150 on the reflection electrode 132 and can expose the conductive material layer 150 on the power line 134 and the pad electrode 136.

Next, referring to FIG. 5G, the conductive material layer 150 can be selectively removed using the third photoresist pattern 196 as an etching mask, thereby forming the first electrode 152, the first dummy pattern 154, and the second dummy pattern 156.

Next, referring to FIG. 5H, the third photoresist pattern 196 can be stripped and removed. Then, the second planarization layer 120 can be formed on the light-emitting element 140, the first electrode 152, the first dummy pattern 154, and the second dummy pattern 156 by applying an organic insulating material substantially all over the substrate 110, and can be patterned through a photolithography process, thereby exposing the adhesive layer 118 on the power line 134 and the pad electrode 136.

Next, the second planarization layer 120 can be partially removed through an ashing process to thereby partially expose the second element electrode of the light-emitting element 140.

Next, referring to FIG. 5I, a fourth photoresist pattern 198 can be formed on the second planarization layer 120 through a photolithography process where photoresist is applied, exposed to light, and developed. The fourth photoresist pattern 198 can cover the second planarization layer 120 and the light-emitting element 140 and can expose the adhesive layer 118 on the power line 134 and the pad electrode 136.

Then, the exposed adhesive layer 118 can be selectively removed using the fourth photoresist pattern 198 as an etching mask, thereby exposing the power line 134 and the pad electrode 136.

Next, referring to FIG. 5J, the fourth photoresist pattern 198 can be stripped and removed, and the second electrode 162 and the auxiliary pad 164 can be formed on the second planarization layer 120 by depositing a conductive material and then patterning it through a photolithography process.

The second electrode 162 can cover the light-emitting element 140 and can be in contact with the exposed second element electrode 142 of the light-emitting element 140. In addition, the second electrode 162 can also be in contact with the power line 134 through the contact hole provided in the adhesive layer 118 and the first and second planarization layers 119 and 120. Further, the auxiliary pad 164 can be in contact with the pad electrode 136 through the contact hole provided in the adhesive layer 118 and the first and second planarization layers 119 and 120.

The second electrode 162 can be configured to overlap the first element electrode 141 as well as the second element electrode 142 considering the margin according to the process deviation. At this time, in the process of forming and then removing the first planarization layer 119 and the first, second, and third photoresist patterns 192, 194, and 196 on the first element electrode 141, if the organic material is not completely removed, the distance between the first electrode 152 connected to the first element electrode 141 and the second electrode 162 connected to the second element electrode 142 can be shorter.

Accordingly, if the second mesa area MS2 is not provided, the first dummy pattern 154 can be connected to the first electrode 152, and the second electrode 162 can be in contact with the first dummy pattern 154, so that the second electrode 162 can be electrically connected to the first electrode 152, and the first element electrode 141 and the second element electrode 142 of the light-emitting element can be electrically short-circuited.

However, in the embodiment of the present disclosure, since the first dummy pattern 154 is separated from the first electrode 152 by the second mesa area MS2, the second electrode 162 can be prevented from being electrically connected to the first electrode 152 even if the second electrode 162 is in contact with the first dummy pattern 154. Accordingly, it is possible to prevent or reduce the electrical short-circuiting between the first element electrode 141 and the second element electrode 142 of the light-emitting element 140.

In the display device according to aspects of of the present disclosure, by providing the first and second mesa areas in the light-emitting element and forming the dummy pattern electrically isolated between the first and second mesa areas, it is possible to prevent or reduce an electrical short-circuiting between the electrodes of the light-emitting element.

According to aspects of the present disclosure, an additional process is not necessary for the light-emitting element and the dummy pattern, so that the manufacturing process of the display device can be optimized and the production energy can be reduced.

It will be apparent to those skilled in the art that various modifications and variations can be made in the display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
a light-emitting element over the substrate, and the light-emitting element including a first element electrode and a second element electrode;
a first electrode electrically connected to the first element electrode; and
a second electrode electrically connected to the second element electrode,
wherein the light-emitting element further includes a first mesa area and a second mesa area spaced apart from each other, and
wherein the second element electrode is disposed in the first mesa area, and the second mesa area is disposed between the first element electrode and the first mesa area.

2. The display device of claim 1, wherein a height of the second mesa area is lower than a height of the first mesa area.

3. The display device of claim 1, further comprising a first dummy pattern between the first mesa area and the second mesa area.

4. The display device of claim 3, wherein the first dummy pattern includes a same material as the first electrode, and is formed over a same layer as the first electrode.

5. The display device of claim 3, further comprising a second dummy pattern including a same material as the first electrode and formed over a same layer as the first electrode,
wherein the first mesa area is disposed between the first dummy pattern and the second dummy pattern.

6. The display device of claim 1, wherein the light-emitting element further includes a first semiconductor layer, a light-emitting layer, and a second semiconductor layer, and
wherein the first mesa area includes the first semiconductor layer, the light-emitting layer, and the second semiconductor layer, and the second mesa area includes the first semiconductor layer.

7. The display device of claim 1, wherein the second electrode overlaps the second mesa area.

8. The display device of claim 1, further comprising a reflection electrode between the substrate and the light-emitting element,
wherein the first electrode is connected to the reflection electrode.

9. The display device of claim 8, further comprising a thin film transistor between the substrate and the reflection electrode,
wherein the reflection electrode is connected to the thin film transistor.

10. The display device of claim 8, further comprising a power line including a same material as the reflection electrode and formed over a same layer as the reflection electrode,
wherein the second electrode is connected to the power line.

11. The display device of claim 1, wherein one of the first and second element electrodes is a p-electrode, while the other of the first and second element electrodes is an n-electrode.

12. The display device of claim 1, wherein one of the first and second element electrodes is a cathode, while the other of the first and second element electrodes is an anode.

13. The display device of claim 1, wherein a width of the second mesa area is smaller than a width of the first mesa area.

14. The display device of claim 5, wherein the first electrode, the first dummy pattern, and the second dummy pattern include a transparent conductive material.

15. The display device of claim 5, wherein the first dummy pattern is separated from the first electrode by the second mesa area.
